(19) United States
(12) Patent Application Publication
(10) Pub. No.: US 2003/0230777 A1
(43) Pub. Date: Dec. 18, 2003

(54) MOSFET and a method for manufacturing the same

(75) Inventors: Toshimitsu Kato, Kanagawa-ken (JP); Yoshiaki Aizawa, Kanagawa-ken (JP); Hiromi Tada, Kanagawa-ken (JP)

Correspondence Address: HOGAN & HARTSON L.L.P., 500 S. GRAND AVENUE, SUITE 1900, LOS ANGELES, CA, 90071-2611, US

(73) Assignee: KABUSHIKI KAISHA TOSHIBA

(21) Appl. No.: 10/406,827

(22) Filed: Apr. 4, 2003

(30) Foreign Application Priority Data
Apr. 14, 2002 (JP) 2002-102604
Apr. 1, 2003 (JP) 2003-097948

(51) Int. Cl. H01L 29/76; H01L 29/94

(52) U.S. Cl. 257/330

(57) ABSTRACT

The MOSFET according to the embodiment of the present invention has an n− type layer 3 formed on the support substrate 1 via a first insulating layer 2. In the active layer 3, an n+ type drain layer 7 and a p type base layer 5 are formed at portions away from each other. An n+ type source layer 6 is formed in a surface region of the base layer 5. A trench gate is formed across the source layer 6, the base layer 5 and the active layer 3. A part of the side wall of the trench gate 10 is in contact with the base layer 5 and the source layer 6 via a second insulating layer 8.

When the MOSFET having thus structured is applied to a photo relay, a high frequency signal can be processed because the product of a capacitance Coff in an off state and a resistance Ron in an on state is small.

### CROSS-REFERENCE TO RELATED APPICATIONS

This application is based upon and claims the benefit of priority from the prior Japanese Patent Applications No.2002-102604 filed on Apr. 14, 2002 and No. 2003-097948 filed on Apr. 1, 2003; the entire contents of which are incorporated herein by reference.

### BACKGROUND OF THE INVENTION

The present invention relates to a MOSFET and more particularly to a MOSFET suited to a photo semiconductor relay (hereinafter referred to as “a photo relay”) used for a circuit for transmitting a high frequency signal such as a semiconductor memory tester or others.

In recent years, the photo relay having an LED on the input side, a photo-diode array (PV) and a MOSFET on the output side is used for a circuit for transmitting a high frequency signal such as a semiconductor memory tester or others. For such photo relay it is required to reduce a capacitance Coff between output terminals of the photo relay at the time of cutting off of a signal in accordance with speeding-up of the processing of the signal.

A VDMOS (a vertical double diffused MOS) having a structure as shown in FIG. 1 has been used as the MOSFET used for the photo relay. With the structure, it is possible to decrease the combined capacitance (Coff) of a capacitance between a drain and a source electrode (CDS) and a capacitance between the drain and a gate electrodes (CDG) at off state of the photo relay by reducing the chip size of the VDMOS. However, there is a limit to decrease Coff and Ron at the same time since the combined capacitance is in a trade-off relationship with an on state resistance (Ron) between the source electrode and the drain electrode at on state.

Therefore, it is extensively studied to improve Ron.A [.cm²] (that is, decreasing a product of Coff and Ron) by reducing the chip size (A) with Ron kept unchanged. Althoug, the UMOS (U-groove MOS) structure shown in FIG. 2 and the LD MOS (lateral double diffused MOS) structure shown in FIG. 3 are proposed for that purpose, they have not sufficiently satisfied the market requirements.

As mentioned above, in a conventional MOSFET, it is difficult to decrease the product of Coff and Ron.

It is therefore an object of the present invention to remove the defects in a conventional MOSFET and to provide a MOSFET having the decreased product of Coff and Ron, which enables high frequency signal processing.

### SUMMARY OF THE INVENTION

Coff of a conventional MOSFET, as mentioned above, is mainly composed of the combined capacitance Coff is composed of CDS and CDG. For example, CDS accounts 80% of Coff in the UMOS structure shown in FIG. 2. This is mainly caused by the base capacitance formed between a p type base layer 5 and an n-type active layer 3.

The inventors have found from the analytical results of the conventional MOSFET structure that in the p type base layer 5, an on state current path 14 includes a waste region 19, which contributes to increase the base capacitance without being used for a current path at on state. Further, the inventors have found that CDS can be decreased by reducing the region, and moreover, Ron.A can be reduced by turning the region into a current path. The present invention has been made based on the knowledge described above.

The MOSFET according to an embodiment of the present invention has a semiconductor layer of a first conductivity type formed on a support substrate via a first insulating layer, a drain layer of the first conductivity type formed in a surface region of the semiconductor layer, a base layer of a second conductivity type formed in the semiconductor layer at a position away from the drain layer, so as to reach the first insulating layer, a source layer of the first conductivity type formed in a surface region of the base layer, a trench groove formed so as to cross the source layer, base layer, and first conductive semiconductor layer in its length and to reach the first insulating layer in its depth, and a gate electrode buried in the trench groove via the second insulating layer, wherein a part of a side wall of the gate electrode is in contact with the base layer and source layer via the second insulating layer.

Further, a method for manufacturing a MOSFET according to an embodiment of the present invention has steps of forming a drain layer of a first conductivity type on a surface of the semiconductor layer of a first conductivity type, which is formed on a support substrate, forming a base layer of a second conductivity type reaching the first insulating layer in the semiconductor layer, forming a source layer of the first conductivity type in a surface of the base layer, forming a trench groove in contact with the base layer and source layer in the semiconductor layer, forming a second insulating film on a side wall of the trench groove and forming a trench gate in the trench groove.

Furthermore, a photo relay device according to an embodiment of the present invention has a light emission element to which a relay control signal is supplied, a photo-diode array for receiving light emitted from the light emission element and for generating a voltage, and a MOSFET defined in any one of claims 1 to 18 having a gate electrode and a source electrode between which the voltage generated by the photo-diode array is supplied.

### BRIEF DESCRIPTION OF THE DRAWINGS

FIG. 1 is a drawing showing a conventional MOSFET,

FIG. 2 is a drawing showing another conventional MOSFET,

FIG. 3 is a drawing showing yet another conventional MOSFET,

FIG. 4 is a drawing showing a method for manufacturing a MOSFET according to an embodiment of the present invention,

FIG. 5 is a drawing showing the method for manufacturing the MOSFET according to the embodiment of the present invention,

FIG. 6 is a drawing showing the method for manufacturing the MOSFET according to the embodiment of the present invention,

FIG. 7 is a drawing showing the method for manufacturing the MOSFET according to the embodiment of the present invention,

FIG. 8 is a plan view showing the MOSFET according to the embodiment of the present invention,

FIG. 9 is a cross sectional view showing the MOSFET according to the embodiment of the present invention,

FIG. 10 is a cross sectional view showing the MOSFET according to the embodiment of the present invention,

FIG. 11 is a cross sectional view showing the MOSFET according to the embodiment of the present invention,

FIG. 12a and FIG. 12b are drawings showing a part of the MOSFET according to the embodiment of the present invention,

FIG. 13a and FIG. 13b are drawings showing the MOSFET according to the embodiment of the present invention,

FIG. 14 is a drawing showing the MOSFET according to the embodiment of the present invention, and

FIG. 15 is a drawing showing a photo relay circuit according to the embodiment of the present invention.

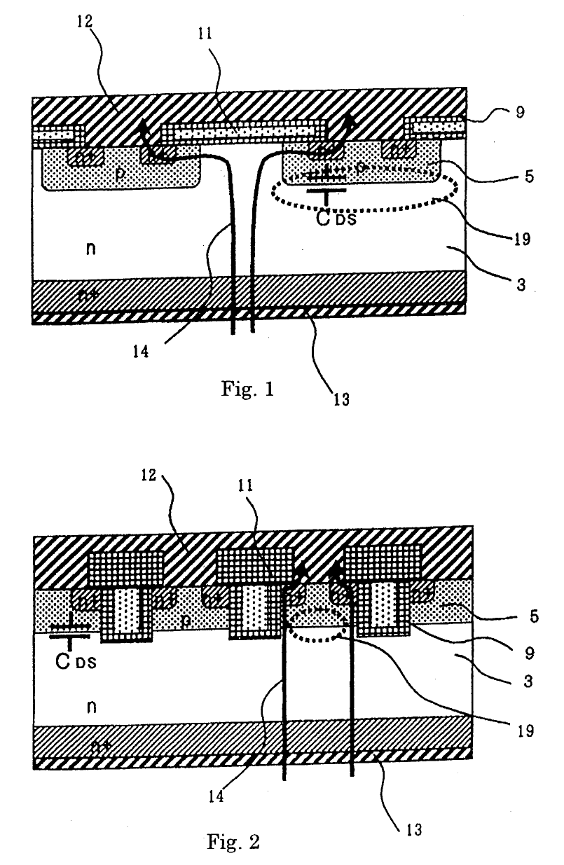

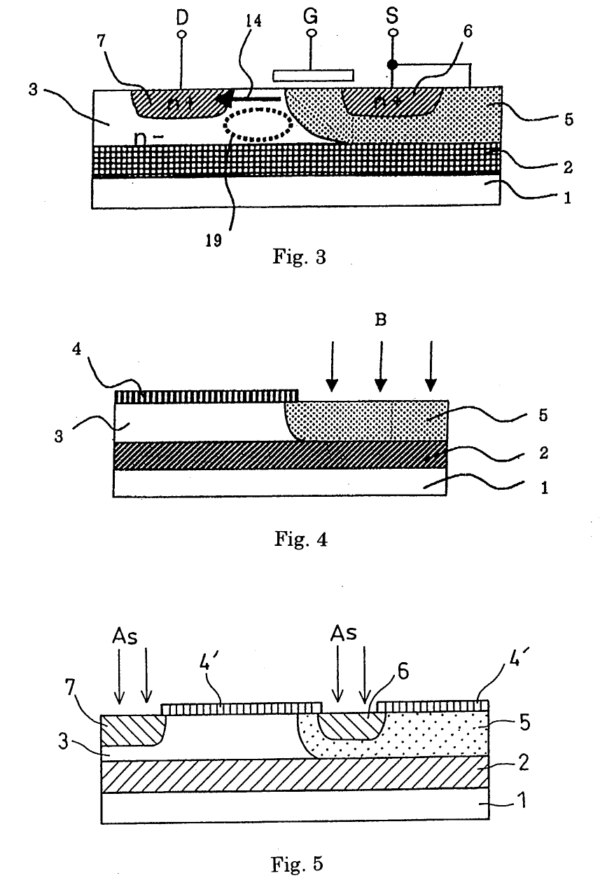

### DETAILED DESCRIPTION OF THE INVENTION

An embodiment of the present invention will be explained hereunder with reference to FIGS. 4 to 15. A method for manufacturing a MOSFET according to an embodiment of the present invention is described with reference to FIGS. 4 to 7.

As shown in FIG. 4, an oxide film 2 (an adhered oxide film) and an n type active layer 3 is sequentially laminated on a support substrate 1 to form an SOI (a silicon on insulator) substrate. Here, the oxide film 2 is adhered on the support substrate 1, for example, by a wafer adhesion technique. On the surface of the SOI substrate thus formed, a photo resist mask 4 is formed, and a p type base layer 5 is formed by injecting boron ions into the active layer 3 through the mask 4.

Then, as shown in FIG. 5, a second photo resist mask 4′ is formed. Arsenic or phosphorus ions are injected in the active layer 3 and the base layer 5, and an n+ type source region 6 and an n+ type drain layer 7 are formed.

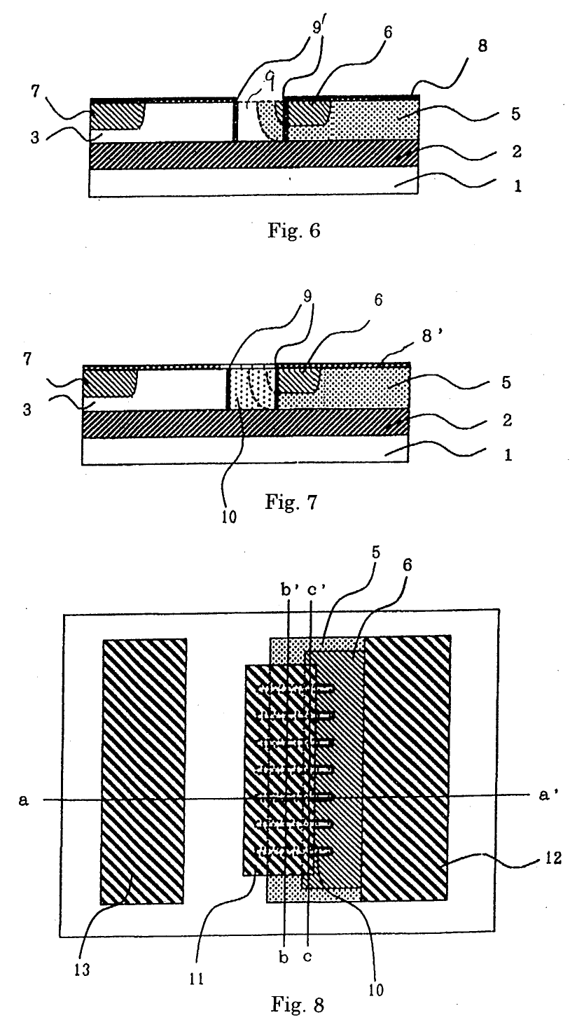

As shown in FIG. 6, a trench groove 9 is formed as a part of a gate electrode in the active layer 3 by RIE (reactive ion etching) using an oxide film 8 patterned in a predetermined shape as a mask. The trench groove 9 is so formed as to reach the oxide film 2 in the depth direction. In its longitudinal direction, the trench groove 9 is so formed as to extend from an edge portion of source region 6 into the active layer 3 through the base layer 5. On inner wall faces of the trench groove 9, a gate insulating film 9′ is formed by thermal oxidation.

As shown in FIG. 7, polysilicon is deposited by a CVD method on overall surface of the substrate 1 in which the trench groove 9 is formed. The surface of the substrate 1 on which the polysilicon is deposited is then etched back using CDE (chemical dry etching) process to the surface of the oxide film 8 to make the surface smooth. A trench gate 10 is thus formed in the trench groove.

Furthermore, an oxide film 8′ is formed overall the substrate 1 and is patterned in a predetermine shape. Another mask layer is thus formed. Thereafter, an aluminum (Al) layer is formed via the mask layer by sputtering. As shown in FIG. 8, the Al layer is so patterned as to form a gate electrode 11, a source electrode 12, and a drain electrode 13.

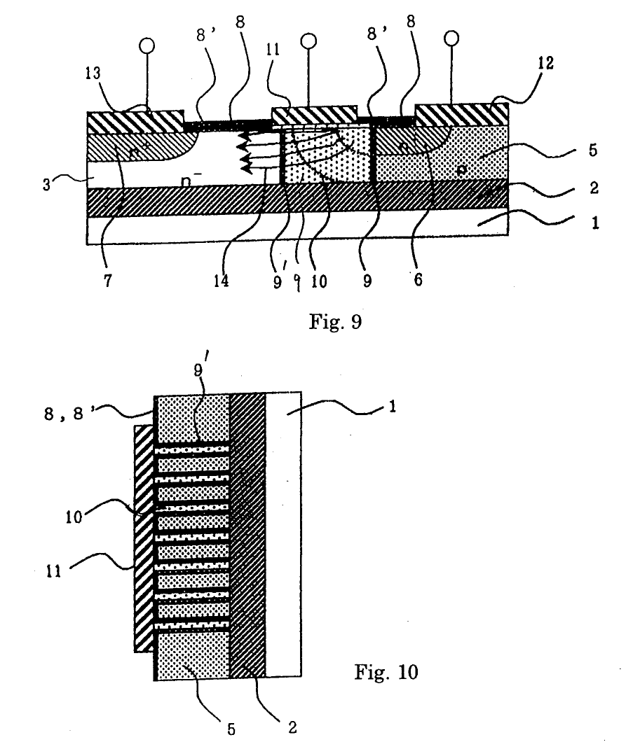

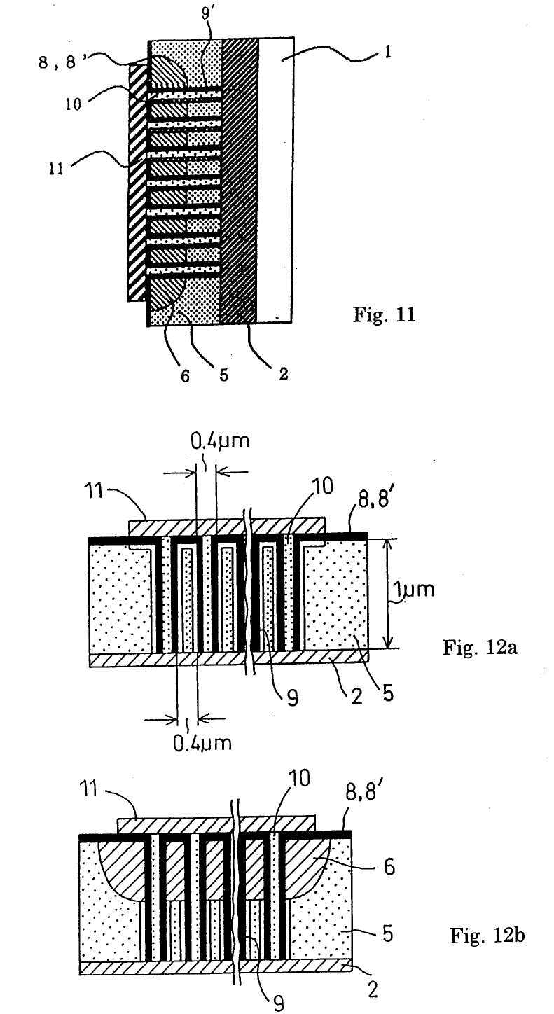

FIG. 8 is a plan view showing an LDMOS having the trench gate structure thus manufactured. Here, FIG. 9 is a sectional view along a line a-a′ shown in FIG. 8. FIG. 10 is also a sectional view along a line b-b′ shown in FIG. 8. FIG. 11 is a sectional view along a line c-c′ shown in FIG. 8. As shown in FIG. 8, the base layer 5, the source layer 6, the drain layer 7 (not seen because it is hidden by the drain electrode 13), the source electrode 12, the drain electrode 13, and the gate electrode 11 are formed so that the plane shapes thereof are almost a strip shape and are arranged in parallel with each other. The trench gate 10 to which the gate electrode 11 is connected is formed so as to cross the stripe-shaped p base layer 5 and source layer 6 in the direction almost perpendicular to the longitudinal direction thereof. The trench gate 10 is so formed that it has a stripe shape in the plan view. A plurality of trench gates 10 are arranged with a space there between in the longitudinal direction of the base layer 5 and source layer 6.

Each of trench gates 10 has a depth reaching the oxide film 2, as shown in FIG. 7. Each of trench gates 10 also has a length extending from the end of the source region 6 into the active layer 3 via base layer 5.

In the MOSFET according to the embodiment of the present invention described, as shown in FIG. 9, the active layer 3 is formed on the support substrate 1 via the insulating layer 2 and the base layer 5 is formed so as to reach the insulating layer 2 in the active layer 3. In the base layer 5, the source layer 5 is formed. The plurality of trench grooves 9 are formed in the active layer 3, which extend across the base layer 5 and the source layer 6. An oxide film 9′ is formed on wall faces of the trench grooves 9. The trench grooves 9 are filled with polysilicon to form the trench gates 10. The trench gates 10 thus formed are electrically connected to the gate electrode 11. The source layer 6 and the base layer 5 are electrically connected to the source electrode 12. The drain layer 7 is formed away from the base layer 5 and is electrically connected to the drain electrode 13.

In the MOSFET having a structure described, when the gate voltage is applied to the gate electrode 11, a gate channel is formed on the surfaces of the source layer 6, the base layer 5 right under the gate electrode 11 and the active layer 3, as well as inside the source layer 6, the base layer 5 below the gate electrode 11 and the active layer 3. Namely, an inner gate channel is formed on the surface of the base layer 5, which is in contact with the oxide film 9′ formed around the trench gates 10. Thus, an on state current path 14 is formed inside the base layer 5, as shown in FIG. 9. Therefore, the base layer 5 effectively contributes to form the on state current path, without forming the waste region as in the conventional FET, so that it is possible to decrease both the CDS (Coff) and the Ron.

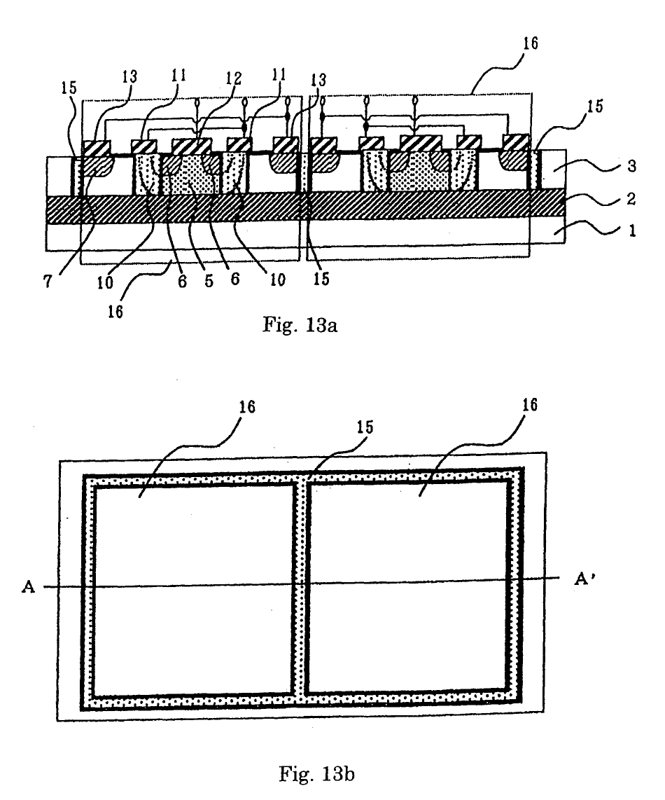

Further detail will be explained hereunder by referring to FIG. 12a and FIG. 12b. FIG. 12a shows the MOSFET shown in FIG. 10 with a part of the central portion removed. FIG. 12b also shows the MOSFET shown in FIG. 11 with a part of the central portion removed. Meanwhile, in a conventional planer gate type MOSFET, the gate channels are formed only in the surface region of the active layer under the gate electrode. Therefore, the channel width of the conventional MOSFET is equal to the width of the gate electrode. On the other hand, in the MOSFET according to the embodiment of the present invention, as shown in FIG. 12a and FIG. 12b, a plurality of trench gates 10 are formed in the active layer under the gate electrode 11 (the p base layer 5 or the source layer 6). Channels are thus formed on the wall faces of the trench grooves 9 in addition to the surface region of the active layer under the gate electrode 11. Now, assuming the width of each of the trench grooves 9 and the space between the adjacent trench grooves 9 respectively as 0.4 μm and the depth of the trench grooves as 1 μm, as shown in FIG. 12a, the channel width per one trench groove 9 is 0.4 μm+1 μm×2=2.4 μm. Since there are two wall faces of each of the trench grooves 9 on both sides of each of the trench gates 10, a value of 2 times of the depth of the trench grooves 9 indicates the channel width in the trench grooves.

As described, in the conventional MOSFET having no trench grooves, the length of the surface region under the gate electrode is the channel width. That is, the channel width of the conventional MOSFET at the portion corresponding to the channel width of the present invention described is 0.4 μm+0.4 μm=0.8 μm. Therefore, the channel width of the present invention is 3 times of the channel width of the conventional MOSFET having the same width of the gate electrode, which enables to decrease Ron to 1/3 of the conventional one.

Furthermore, the trench gates reduce a diffusion area of the base layer 5, that is, an area of the base layer 5 facing the adjacent active layer 3 since ends of the trench gates extend into the active layer 3. The reduction rate is about ½ of the whole area of the base layer 5 facing the adjacent active layer 3, so that Cds can be reduced to about ½. The Cds accounts for 80 percent of Coff, so that Coff is reduced to ⅗. Therefore, the product of Coff and Ron is reduced to ⅕.

Although in the above embodiment the trench groove 9 is so formed as to reach the oxide film 2 in the depth direction, it is not necessary. However, the depth of the trench groove 9 is desirable to be deeper than the source region 6. The reason is that Ron becomes suddenly decrease due to decrease in a current pass contributing to Ron if the depth of the trench groove 9 is not deeper than the source region 6.

FIG. 13a and FIG. 13b are drawings showing a semiconductor chip, in which a pair of MOSFETs according to the above embodiment of the present invention is formed on the same semiconductor substrate. FIG. 13a show a cross sectional view along a line A-A′ shown in FIG. 13b, which is a plan view of the pair of MOSFETs. As shown in these drawings, the n type active layer 3, the p type base layer 5, the n+ type layer 6 and the n+ type layer 7 are formed on the SOI substrate as is the case with the above embodiment. Thereafter, trench grooves for the trench gates 10 and grooves 15 for isolating elements are formed by RIE using a patterned oxide film as a mask, which reach the oxide film 2. Thereafter, the gate insulating films 9′ are formed on wall faces of the respective trench grooves 9′ using a thermal oxidation method.

Thereafter, the respective trench grooves 9 are filled with polysilicon and electrodes are formed. The LDMOS having a pair of MOSFETs 16 of the trench gate structure is thus formed in one chip, in which each of the MOSFET 16 is isolated by the element isolating grooves 15.

The conventional photo relay is generally composed of one chip photo-diode array (PV) and two chips of MOSFET on the output side. By use of such a structure, however, the two chips of MOSFETs can be integrated into one chip. Further, the whole of the photo relay can be integrated into one chip, which reduces the steps of manufacturing the chip.

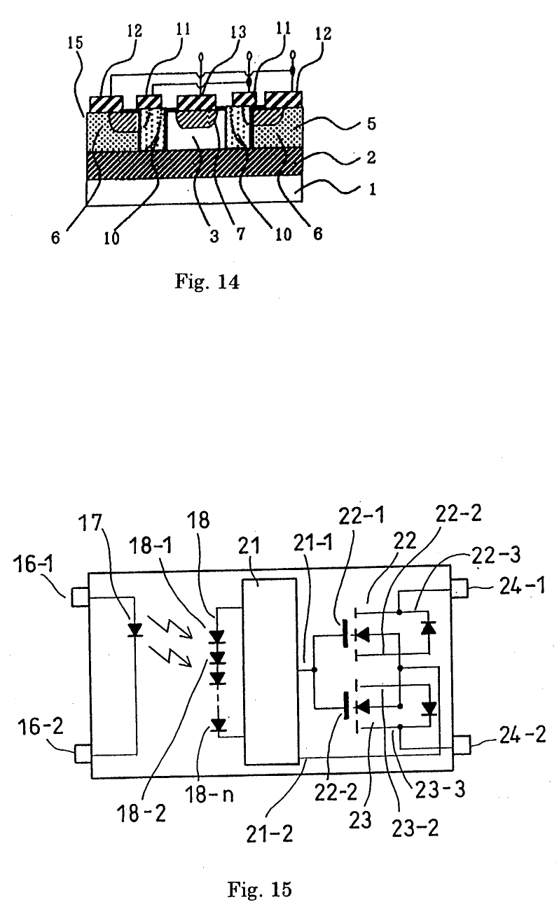

Alternatively, the structure of the MOSFET shown in FIG. 14 may be so modified that the source and base regions are changed with the drain region in their positions.

FIG. 15 is a circuit diagram of a photo relay device shown as an example of an application device using the MOSFET according to the above embodiment of the present invention. In the photo relay device, a light emission element (LED) 17 is connected between input terminals 16-1 and 16-2. The LED 17 emits light when a relay control signal is applied between the input terminals 16-1 and 16-2. The emitted light is received by a photo-diode array (PV) 18 which is arranged opposite to and separated from the LED 17. The PV 18 is composed of a plurality of photo-diodes 18-1, - - - , and 18-n connected in series. The PV 18 generates at both ends a DC voltage, which is equal to n times as large as the electromotive force of each of the photo-diodes 18-1, - - - , and 18-n, upon receipt of the light from the LED 17. The DC voltage is supplied to the input side of a control circuit 20 and then supplied via one of output terminals 21-1 of the control circuit 20 to gate electrodes 22-1 and 23-1 commonly connected with each other of a pair of MOSFETs 22 and 23. Another one of the output terminals 21-2 of the control circuit 20 is connected to source electrodes 22-2 and 23-2 commonly connected with each other of the MOSFETs 22 and 23. Drain electrodes 22-3 and 23-3 of the MOSFETs 22 and 23 are connected to output terminals 24-1 and 24-2 of the photo relay device respectively.

The control circuit 20 supplies the output voltage of the PV between the gate electrodes 22-1 and 23-1 commonly connected and the source electrodes 22-2 and 23-2 commonly connected. Further, the control circuit 20 includes a discharge circuit for quickly discharging a charge stored between the gate electrodes 22-1 and 23-1 commonly connected and the source electrodes 22-2 and 23-2 commonly connected, when the output voltage of the PV is not supplied.

The operation of the photo relay device thus formed will be explained bellow. When a relay control signal is applied between the input terminals 16-1 and 16-2, that is, when the relay control signal turned into on state, the LED emits light. The PV 18 receives the emitted light. The PV, upon receipt of the light, generates a DC voltage at both ends thereof. The voltage is supplied to the input side of the control circuit 20 and via the output terminals 21-1 and 21-2, is supplied between the gate electrodes 22-1 and 23-1 commonly connected and the source electrodes 22-2 and 23-2 commonly connected.

The MOSFETS 22 and 23 are made conductive. When the MOSFETs 22 and 23 are made conductive, the output terminals 24-1 and 24-2 of the photo relay device to which the MOSFETs 22 and 23 are connected in series are electrically connected with each other. It means that the photo relay device is in the on state.

When the relay control signal is not applied between the input terminals 16-1 and 16-2, that is, when the relay control signal enters into an off state, the LED 17 does not emit the light. Since the PV 18 does not receive light any more, the DC voltage, which has been generated at both ends, is decreased to 0 V. The voltage between the output terminals 21-1 and 21-2 of the control circuit 20 also becomes 0 V. The voltage, which has been applied between the gate electrodes 22-1 and 23-1 commonly connected and the source electrodes 22-2 and 23-2 commonly connected, becomes 0 V.

The MOSFETs 22 and 23 are thus made conductive. When the MOSFETs 22 and 23 are made conductive respectively, the output terminals 24-1 and 24-2 of the photo relay device to which the MOSFETs 22 and 23 are connected in series are electrically connected with each other. It means that the photo relay device is in the off state. In the off state of the photo relay device, the control circuit 20, quickly discharges the charge stored between the gate electrodes 22-1 and 23-1 commonly connected and the source electrodes 22-2 and 23-2 commonly connected by the discharge circuit as mentioned above. The switching time of the photo relay device from the on state to the off state is shortened.

In the photo relay device having a circuit constitution, Ron, which is an electrical resistance between the output terminals 24-1 and 24-2 of the photo relay device in the on state, can be reduced, when the FET having the structure according to the embodiment of the present invention is used. Further, the amount of charge stored in the on state is reduced since the capacitance Coff between the source and drain electrodes of the FET of the photo relay device in the off state is small. As a result, the switching time from the on state of the photo relay device to the off state is more shortened.

According to the present invention thus described, a high speed operation for switching a signal on and off at high frequency is available since the product of Coff and Ron is small, which is an index indicating the capacitance of the photo relay device. Therefore, a photo relay device using the FET according to the present invention can be used for such a circuit for transmitting a high frequency signal as a tester for a semiconductor memory, which enables to respond to a high speed processing of test signals.

What is claimed is:

1. A MOSFET comprising:
a semiconductor layer of a first conductivity type formed on a support substrate via a first insulating layer;
a drain layer of a first conductivity type formed in a surface region of the semiconductor layer;
a base layer of a second conductivity type formed in the semiconductor layer at a portion away from the drain layer so as to reach the first insulating layer;
a source layer of the first conductivity type formed in a surface region of the base layer;
a trench groove formed across the source layer, the base layer and the semiconductor layer; and
a trench gate buried in the trench groove via a second insulating layer;
wherein a part of a side surface of the trench gate is in contact with the base layer and the source layer via the second insulating layer.

2. A MOSFET claimed in claim 1, wherein the drain layer, the base layer and the source layer have a stripe shape, in their plane views, which are arranged in substantially parallel with respect to their longitude of the stripe shape, the trench gate is formed across the longitude of the stripe shaped base layer and source layer, and a plurality of trench gates are arranged with a space between the adjacent ones in the longitudinal direction of the stripe shaped base layer and source layer.

3. A MOSFET claimed in claim 2, wherein the plurality of trench gates has a stripe shape, in the plan view and one end of each of the stripe shaped trench gates is extended into the semiconductor layer adjacent to the base layer.

4. A MOSFET according to claim 3, wherein the plurality of trench gates has a stripe shape in the plane view, and the space between the adjacent trench gates is substantially equal to a width of the stripe shaped trench gates.

5. A MOSFET claimed in claim 3, wherein a gate channel is formed on the surfaces of the source layer, the base layer, and the conductive semiconductor layer under the gate electrode, as well as inside the source layer, the base layer, and the conductive semiconductor layer under the gate electrode, when a gate voltage is applied to the gate electrode.

6. A MOSFET according to claim 5, wherein the gate channel formed inside the source layer, the base layer, and the first conductive semiconductor layer under the gate electrode is formed at a portion, which is in contact with the second insulating layer formed on a surface of the plurality of trench gates.

7. A MOSFET comprising:
a semiconductor layer of a first conductivity type formed on a support substrate via a first insulating layer;
a drain layer of the first conductivity type formed in a surface region of the semiconductor layer;
a base layer of a second conductivity type formed in the semiconductor layer at a portion away from the drain layer so as to reach the first insulating layer;
a source layer of the first conductivity type formed in a surface region of the base layer;
a trench groove formed across the source layer, the base layer, and the semiconductor layer and with a depth deeper than the source layer; and
a trench gate buried in the trench groove via a second insulating layer;
wherein a part of a side wall of the trench gate is in contact with the base layer and the source layer via the second insulating layer.

8. A MOSFET claimed in claim 6, wherein the drain layer, the base layer and the source layer have a stripe shape, in their plane views, which are arranged in substantially parallel with respect to their longitude of the stripe shape, the trench gate is formed across the longitude of the stripe shaped base layer and source layer, and a plurality of trench gates are arranged with a space between the adjacent ones in the longitudinal direction of the stripe shaped base layer and source layer.

9. A MOSFET claimed in claim 8, wherein the plurality of trench gates has a stripe shape, in the plan view and one end of each of the stripe shaped trench gates is extended into the semiconductor layer adjacent to the base layer.

10. A MOSFET claimed in claim 9, wherein a gate channel is formed on the surfaces of the source layer, the base layer, and the conductive semiconductor layer under the gate electrode, as well as inside the source layer, the base layer, and the conductive semiconductor layer under the gate electrode, when a gate voltage is applied to the gate electrode.

11. A MOSFET claimed in claim 10, wherein the gate channel formed inside the source layer, the base layer, and the first conductive semiconductor layer under the gate electrode is formed at a portion, which is in contact with the second insulating layer formed on a surface of the plurality of trench gates.

12. A MOSFET claimed in claim 11, wherein the plurality of trench gates has a stripe shape in the plane view, and the space between the adjacent trench gates is substantially equal to a width of the stripe shaped trench gates.

13. A MOSFET claimed in claim 12, wherein the plurality of trench gates have a depth in the sectional view, which is substantially equal to the length of the stripe shaped trench gates in the plan view.

14. A method for manufacturing a MOSFET comprising steps of:
forming a drain layer of a first conductivity type on a surface of a semiconductor layer of the first conductivity type, which is formed on a support substrate;
forming a base layer of a second conductivity type in the semiconductor layer;
forming a source layer of the first conductivity type on a surface of the base layer;
forming a trench groove, which is in contact with the base layer and the source layer in the semiconductor layer; and
forming a insulating film on a wall of the trench groove and forming a trench gate therein.

15. A method for manufacturing a MOSFET claimed in claim 14, wherein the drain layer, the base layer and the source layer have a stripe shape, in their plane views, which are arranged in substantially parallel with respect to their longitude of the stripe shape, the trench gate is formed across the longitude of the stripe shaped base layer and source layer, and a plurality of trench gates are arranged with a space between the adjacent ones in the longitudinal direction of the stripe shaped base layer and source layer.

16. A method for manufacturing a MOSFET claimed in claim 15, wherein the plurality of trench gates has a stripe shape, in the plan view and one end of each of the stripe shaped trench gates is extended into the semiconductor layer adjacent to the base layer.

17. A method for manufacturing a MOSFET claimed in claim 16, further comprising a step of forming an isolating groove in the semiconductor layer, as well as the trench groove.

18. A photo relay device comprising:
a light emission element to which a relay control signal is supplied;
a photo-diode array for receiving light emitted from the light emission element and for generating a voltage; and
a MOSFET according to any of claims 1 to 18 that the output voltage of the photo-diode array is supplied between a gate electrode and a source electrode.

19. A photo relay device claimed in claim 23, wherein the MOSFET comprises two MOSFETs, in which the gate electrodes are commonly connected to each other and the source electrodes are commonly connected to each other.

20. A photo relay device claimed in claim 19, wherein a control circuit is connected between the photo-diode array and the MOSFET, including a circuit for discharging a charge stored between the gate electrode and source electrode of the MOSFET while the relay control signal is in an on state, when the relay control signal is changed from an on state to an off state.
